(19) United States
(12) Patent Application Publication
(10) Pub. No.: US 2010/0065215 A1
(43) Pub. Date: Mar. 18, 2010

(54) Plasma generating apparatus

(75) Inventors: Sang Jean Jeon, Hwaseong-si (KR); Yuri Tolmachev, Suwon-si (KR); Vasily Pashkovskiy, Suwon-si (KR); Kee Soo Park, Suwon-si (KR); Ju Hyun Lee, Suwon-si (KR); Su Ho Lee, Seongnam-si (KR); Chan Yun Lee, Suwon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/585,098

(22) Filed: Sep. 3, 2009

(30) Foreign Application Priority Data
Sep. 17, 2008 (KR) 10-2008-0090872

(51) Int. Cl. C23C 16/513; H01L 21/3065

(52) U.S. Cl. 156/345.48; 118/723 I; 134/58 R

(57) ABSTRACT

A plasma generating apparatus including a plurality of plasma source modules. Each plasma source module includes a ferrite core having high magnetic permeability and a plasma channel through which plasma may pass. The plasma generating apparatus may effectively generate and uniformly distribute large-area and high-density plasma without a dielectric window.

### CROSS-REFERENCE TO RELATED APPLICATION(S)

This application claims priority under 35 U.S.C. §119 to Korean Patent Application No. 10-2008-0090872, filed Sep. 17, 2008 in the Korean Intellectual Property Office (KIPO), the entire contents of which is incorporated herein by reference.

### BACKGROUND

1. Field

The general inventive concept relates to a plasma generating apparatus, and, more particularly, to a plasma generating apparatus that may be capable of improving plasma generating efficiency using a ferrite core.

2. Description of the Related Art

Plasma is an ionized gas that may consist of cations, anions, electrons, excited atoms, molecules, and/or highly chemically active radicals. Plasma is called “the fourth state of matter” because plasma has different electrical and thermal properties from normal gases. Plasma may cause acceleration of chemical reactions of an ionized gas by use of an electric and/or magnetic field and has been valuably utilized in fabrication processes of semiconductors. For example, plasma has been utilized to clean and/or etch semiconductor wafers and/or substrates. Plasma has also been used in various deposition processes associated with semiconductor wafer and/or substrate fabrication.

An Inductively Coupled Plasma (ICP) generating apparatus may be used to generate high-density plasma. In a conventional ICP generating apparatus, a process gas is introduced into a chamber in which plasma is generated, and high-frequency electricity is applied to a high-frequency antenna which is located near a dielectric window at the top of the chamber, whereby an inductive electric field is created in the chamber by means of the dielectric window. The inductive electric field ionizes the process gas, generating plasma inductively coupled with the antenna. The plasma may be used to clean and/or etch an object, for example, a semiconductor wafer or substrate, placed on an electrode at the bottom of the chamber. Although conventional ICP generating apparatuses are used in the semiconductor field, the conventional ICP generating apparatuses have a limit in the generation of large-area and high-density plasma.

### SUMMARY

The general inventive concept provides a plasma generating apparatus capable of generating and uniformly distributing large-area and high-density plasma.

Additional aspects and/or advantages of the general inventive concept will be set forth in part in the description which follows and, in part, will be obvious from the description, or may be learned by practice of the general inventive concept.

In accordance with an example embodiment of the present invention, a plasma generating apparatus may include a reactor chamber configured for plasma generation, an RF generator configured to supply RF power, at least one antenna system including a plurality of plasma source modules to create an inductive electric field in the plasma upon receiving the RF power, and an electrode in the reactor chamber configured to support a workpiece.

In accordance with an example embodiment of the present invention, a plasma generating apparatus may include a reactor chamber for plasma generation, an RF generator configured to supply RF power for plasma generation, a plurality of plasma source modules each including a closed-loop shaped ferrite core configured to create an inductive electric field in the plasma upon receiving the RF power, and a plasma channel defining a space to create a closed loop of plasma current by the inductive electric field in conjunction with the reactor chamber, and an antenna coil configured to connect the plurality of plasma source modules in series.

The foregoing and/or other aspects and utilities of the general inventive concept may be achieved by providing a plasma generating apparatus including a reactor chamber in which plasma is generated, an RF generator to supply RF power for plasma generation, an antenna system including a plurality of plasma source modules to create an inductive electric field in the plasma upon receiving the RF power, and an electrode on which a workpiece put into the reactor chamber is placed, the RF power being applied to the electrode.

Each of the plasma source modules may include a closed-loop shaped ferrite core, and a plasma channel defining a space to create a closed loop of plasma current by the inductive electric field in conjunction with the reactor chamber.

The ferrite core may have a square ring form.

The ferrite core may be disposed perpendicular to an upper surface of the reactor chamber.

The plasma channel may have an inverted U-shaped form to reduce the loss of plasma.

The plasma channel may be provided with a gas nozzle.

The plasma channel may be a metal tube or ceramic tube, and when the plasma channel is the metal tube, a DC brake to prevent current from being induced in the plasma channel may be further provided.

The plurality of plasma source modules of the antenna system arranged on an upper surface of the reactor chamber may be connected with one another in series by an antenna coil connected with the RF generator.

The antenna system may include a first group of the plasma source modules arranged in a peripheral region of an upper surface of the reactor chamber, and a second group of the plasma source modules arranged in a central region of the upper surface of the reactor chamber, and the plasma source modules of each group may be connected with one another in series by use of an independent antenna coil.

The plurality of plasma source modules arranged on an upper surface of the reactor chamber may be divided into groups of the same number of plasma source modules, and the plasma source modules of each group may be connected with one another in series by use of an independent antenna coil.

The foregoing and/or other aspects and utilities of the general inventive concept may be achieved by providing a plasma generating apparatus including a reactor chamber in which plasma is generated, an RF generator to supply RF power for plasma generation, a plurality of plasma source modules each including a closed-loop shaped ferrite core to create an inductive electric field in the plasma upon receiving the RF power, and a plasma channel defining a space to create a closed loop of plasma current by an inductive electric field in conjunction with the reactor chamber; and an antenna coil to connect the plurality of plasma source modules in series.

The ferrite core may have a closed-looped shaped form and is disposed perpendicular to an upper surface of the reactor chamber, and the plasma channel may have an inverted U-shaped form to reduce the loss of plasma. As shown in FIG. 5, the ferrite core may be square form. When the plasma channel is a metal tube, a DC brake to prevent current from being induced to the plasma channel may be further provided.

The plurality of plasma source modules may include a first group of the plasma source modules arranged in a peripheral region of an upper surface of the reactor chamber, and a second group of the plasma source modules arranged in a central region of the upper surface of the reactor chamber, and the plasma source modules of each group are connected with one another in series by use of the independent antenna coil.

The plurality of plasma source modules may be divided into groups of the same number of plasma source modules and the plasma source modules of each group may be connected with one another in series by use of the independent antenna coil.

In a plasma generating apparatus in accordance with any aspect of the general inventive concept as described above, with the presence of a ferrite core having high magnetic permeability and a plurality of plasma source modules each having a plasma channel through which plasma passes, large-area and high-density plasma may be effectively generated and uniformly distributed without configuration of a dielectric window.

### BRIEF DESCRIPTION OF THE DRAWINGS

These and/or other aspects and advantages of the general inventive concept will become apparent and more readily appreciated from the following description of the embodiments, taken in conjunction with the accompanying drawings, of which:

FIG. 1 is a sectional view illustrating a plasma generating apparatus in accordance with an embodiment of the general inventive concept;

FIG. 2 is a plan view illustrating the plasma generating apparatus in accordance with an embodiment of the general inventive concept;

FIG. 3 is a plan view illustrating a plasma generating apparatus in accordance with another embodiment of the general inventive concept;

FIG. 4 is a view illustrating a plasma source module of FIG. 1;

FIG. 5 is a sectional view taken along line A-A′ of FIG. 4;

FIG. 6 is a plan view illustrating a DC brake of FIG. 4; and

FIG. 7 is a view illustrating an equivalent circuit for a plasma generating apparatus in accordance with a further embodiment of the general inventive concept.

### DETAILED DESCRIPTION

Example embodiments of the present invention will now be described more fully with reference to the accompanying drawings, in which the example embodiments are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the drawings, the sizes of components may be exaggerated for clarity.

It will be understood that when an element or layer is referred to as being “on”, “connected to”, or “coupled to” another element or layer, it can be directly on, connected to, or coupled to the other element or layer or intervening elements or layers that may be present. In contrast, when an element is referred to as being “directly on”, “directly connected to”, or “directly coupled to” another element or layer, there are no intervening elements or layers present. As used herein, the term “and/or” includes any and all combinations of one or more of the associated listed items.

It will be understood that, although the terms first, second, etc. may be used herein to describe various elements, components, regions, layers, and/or sections, these elements, components, regions, layers, and/or sections should not be limited by these terms. These terms are only used to distinguish one element, component, region, layer, and/or section from another element, component, region, layer, and/or section. Thus, a first element, component, region, layer, or section discussed below could be termed a second element, component, region, layer, or section without departing from the teachings of example embodiments.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Embodiments described herein will refer to plan views and/or cross-sectional views by way of ideal schematic views. Accordingly, the views may be modified depending on manufacturing technologies and/or tolerances. Therefore, example embodiments are not limited to those shown in the views, but include modifications in configuration formed on the basis of manufacturing processes. Therefore, regions exemplified in figures have schematic properties and shapes of regions shown in figures exemplify specific shapes or regions of elements, and do not limit example embodiments. Reference will now be made in detail to a plasma generating apparatus in accordance with exemplary embodiments of the general inventive concept, examples of which are illustrated in the accompanying drawings, wherein like reference numerals refer to like elements throughout. The embodiments are described below to explain the general inventive concept by referring to the figures.

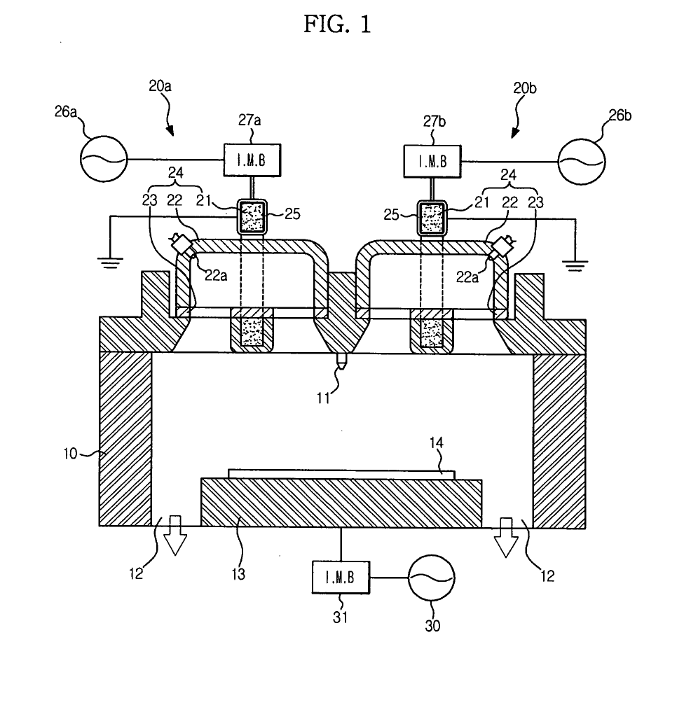

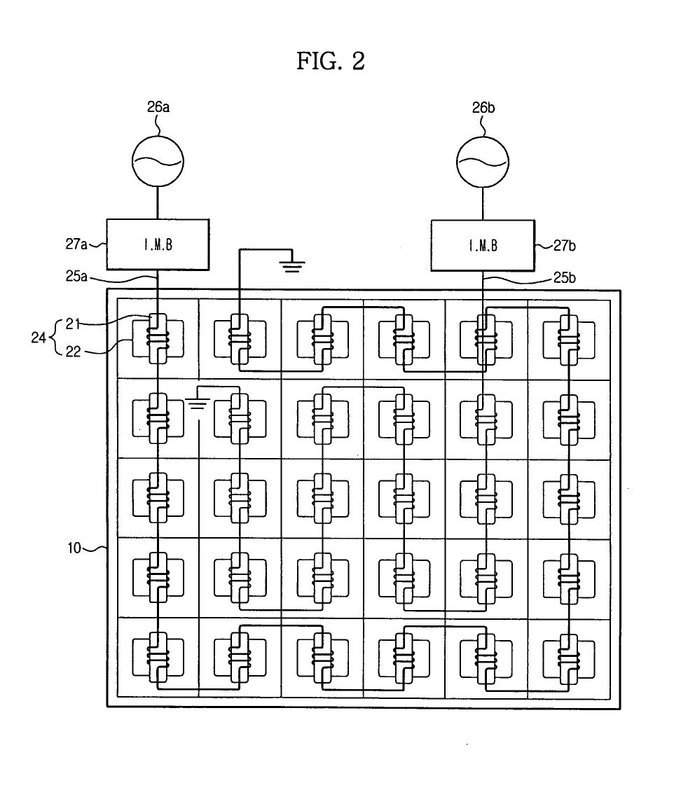

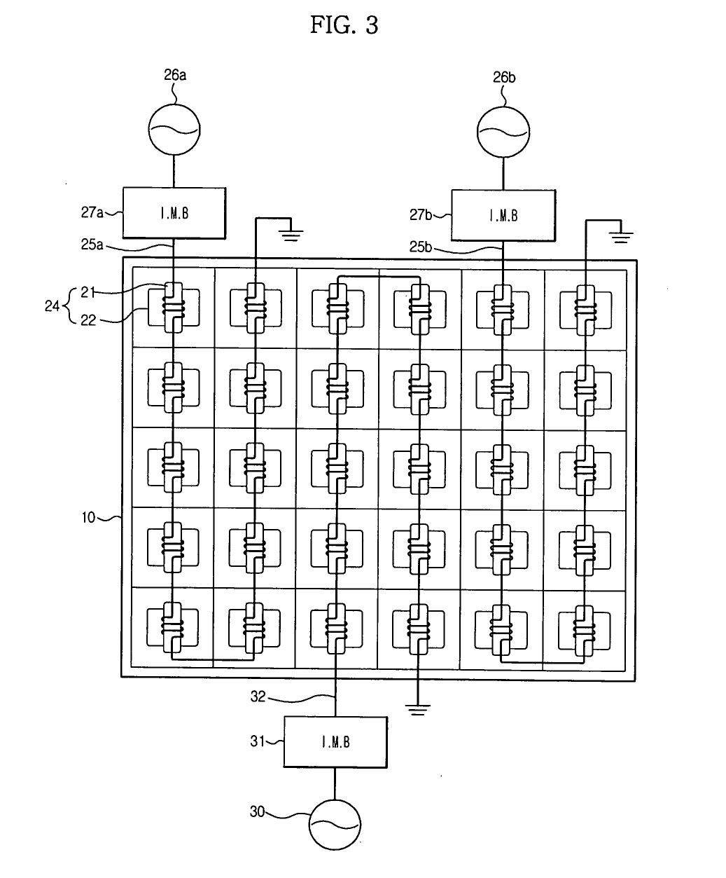

FIG. 1 is a sectional view illustrating a plasma generating apparatus in accordance with an embodiment of the general inventive concept, and FIG. 2 is a plan view of the plasma generating apparatus in accordance with the embodiment of the general inventive concept. Also, FIG. 3 is a plan view illustrating a plasma generating apparatus in accordance with another embodiment of the general inventive concept.

Referring to FIGS. 1 to 3, the plasma generating apparatus in accordance with the embodiments of the general inventive concept may include a vacuum reactor chamber 10 in which plasma generated via ionization of an injected gas may be stored, and an antenna system provided at the top of the reactor chamber 10 to generate plasma in the reactor chamber 10. In FIG. 1, two antenna systems 20a and 20b are illustrated.

The reactor chamber 10 defines an interior reaction space, in which plasma generation may occur and desired processes of a workpiece, for example, a semiconductor wafer or a glass substrate, using plasma may be performed. The reactor chamber 10 may include functions to maintain a predetermined or given vacuum pressure and temperature in the reaction space. The reactor chamber 10 may be provided with a gas nozzle 11 to inject a reactant gas from an external source into the reaction space, and an exhaust 12 to discharge the reactant gas out of the reactor chamber 10 after completion of a reaction. In addition, the reactor chamber 10 may contain an electrode 13 on which a workpiece 14, for example, a semiconductor wafer or a glass substrate, may be placed.

The plasma generating apparatus in accordance with the embodiments of the general inventive concept may further include an RF generator 30 to apply RF power of a particular frequency band (for example, several tens KHz to several MHz) to the electrode 13 in the reactor chamber 10, and an impedance matching box 31 to transmit the RF power of the RF generator 30 to the electrode 13 without loss. Although described in more detail hereinafter, initial plasma generation may occur as the RF generator 30 applies RF power to the electrode 13 to cause plasma ignition in a Capacitively Coupled Plasma (CCP) manner.

Antenna systems may include a plurality of plasma source modules 24, antenna coils 25 wound on the plurality of plasma source modules 24, RF generators 26a and 26b to apply RF power of a particular frequency band (for example, 400 KHz to 2 MHz) to the antenna coils 25, and impedance matching boxes 27a and 27b to transmit the RF power to the antenna coils 25 without loss.

Each of the plasma source modules 24 may include a ferrite core 21 on which an associated antenna coil may be wound, and a plasma channel 22 defining a space to create a closed loop of plasma current, as will be described hereinafter, in conjunction with the reactor chamber 10.

The plurality of plasma source modules 24, each including a ferrite core 21 and a plasma channel 22, may be equidistantly arranged on an upper surface of the reactor chamber 10. A connecting arrangement of the several plasma source modules is illustrated in FIGS. 2 to 4.

As illustrated in FIG. 2, in one embodiment of the general inventive concept, thirty plasma source modules 24 may be arranged in a grid pattern throughout the upper surface of the reactor chamber 10. The embodiment illustrated in FIG. 2 includes two independent RF generators 26a and 26b, however, the inventive concept is not limited to two independent RF generators. The RF generator 26a may achieve grounding of eighteen plasma source modules 24 which may be arranged in a peripheral region of the upper surface of the reactor chamber 10 and may be connected in series by use of an antenna coil 25a. The RF generator 26b may achieve grounding of twelve plasma source modules 24 which may be arranged in a central region of the upper surface of the reactor chamber 10 and may be connected in series by use of an antenna coil 25b. In this example, plasma density in the peripheral region may be lower than the plasma density in the central region and therefore, uniform plasma may be generated by adjusting RF power of the corner regions.

In another embodiment of the general inventive concept, as illustrated in FIG. 3, thirty plasma source modules 24 may be arranged in a grid pattern throughout the upper surface of the reactor chamber 10. The embodiment illustrated in FIG. 3 includes three independent RF generators 26a, 26b, and 30, however, the inventive concept is not limited to three independent RF generators. The RF generator 26a may achieve grounding of ten plasma source modules 24 which may be arranged in a left region of the upper surface of the reactor chamber 10 and may be connected in series by use of an antenna coil 25a. The RF generator 30 may achieve grounding of ten plasma source modules 24 which may be arranged in a middle region of the upper surface of the reactor chamber 10 and may be connected in series by use of an antenna coil 32. The RF generator 26b may achieve grounding of ten plasma source modules 24 which may be arranged in a right region of the upper surface of the reactor chamber 10 and may be connected in series by use of an antenna coil 25b. In this example, different numbers of plasma source modules 24 may be connected to the respective RF generators 26a, 26b and 30.

As illustrated in FIGS. 2 and 3, the plurality of plasma source modules 24 may be arranged throughout the upper surface of the reactor chamber 10. These example arrangements of source modules may achieve the generation and uniform distribution of a high-density plasma over a large-area. The configuration of FIG. 2, wherein different numbers of plasma source modules 24 may be connected to different RF generators may have a difference in RF power transmitted to the plasma source modules. The configuration of FIG. 3, wherein the same number of plasma source modules 24 may be connected to different RF generators may exhibit not only equal transmission of RF power per each plasma source module 24, but may also exhibit equal operation of impedance matching boxes 27a, 27b and 31.

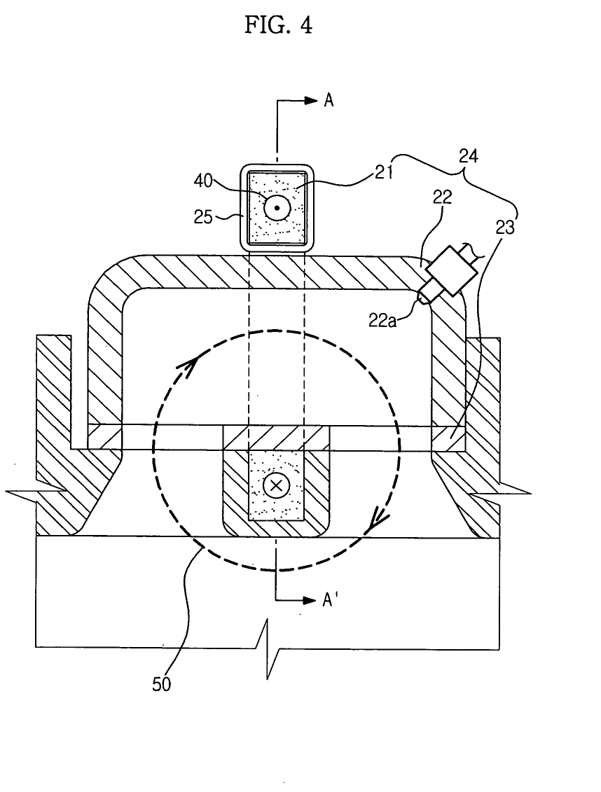

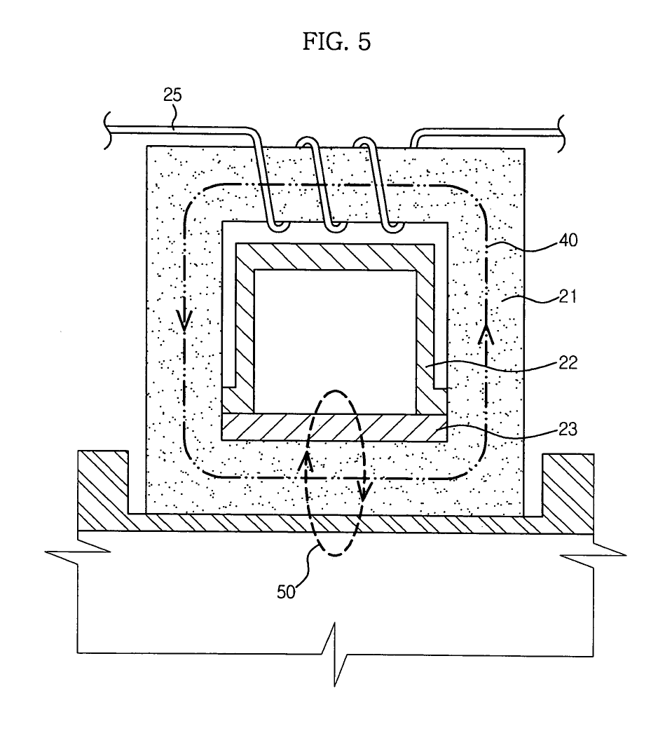

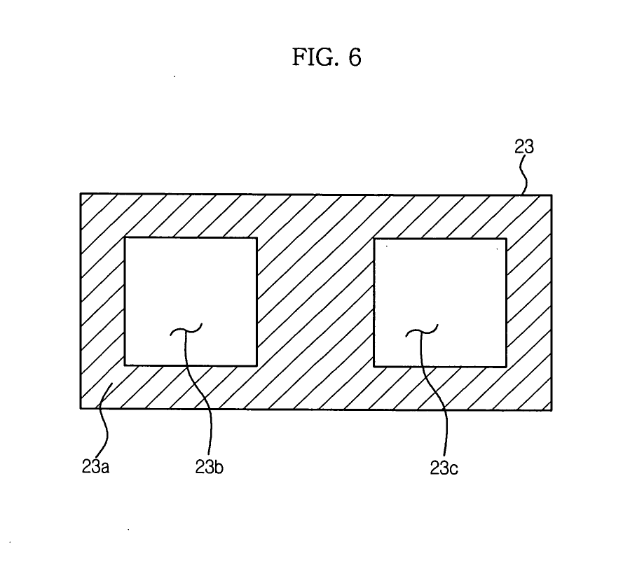

FIG. 4 is an enlarged view illustrating the plasma source module of FIG. 1. FIG. 5 is a sectional view taken along line A-A′ of FIG. 4. FIG. 6 is a plan view illustrating a DC brake of FIG. 4.

The configuration of a plasma source module 24 having a ferrite core 21 and a plasma channel 22 will be described in detail with reference to FIGS. 4 and 5.

As shown in FIG. 5, the ferrite core 21 may have a square ring form. If RF power is applied to the antenna coil 25 wound on a primary-side of the ferrite core 21, a magnetic field 40 as a closed loop around the ferrite core 21 may be created by a high-frequency current flowing through the primary-side. The magnetic field may be transmitted to plasma around a secondary-side of the ferrite core 21. As shown in FIG. 5, an inductive electric field 50 may be created at the secondary-side of the ferrite core 21. To effectively transmit the magnetic field 40 to plasma around the secondary-side, the ferrite core 21 may have a square ring form and may be disposed perpendicular to the upper surface of the reactor chamber 10. Accordingly, a conventional dielectric wire may be eliminated.

The plasma channel 22 may be provided in the ferrite core 21 such that a path of plasma current induced in plasma around the secondary-side of the ferrite core 21 defines a closed loop in conjunction with a wall surface of the reactor chamber 10. In other words, the plasma channel 22 may define a space providing a closed loop of plasma current. Accordingly, the plasma channel 22 may induce current in the plasma by absorbing RF power applied from the RF generators 26a and 26b. The wall surface of the reactor chamber 10 and the plasma channel 22 may constitute the path of high-frequency current induced in the secondary-side plasma.

As shown in FIGS. 4 and 5, the plasma channel 22 may have an inverted U-shaped form. The inverted U-shape may reduce or prevent the loss of plasma in the plasma channel 22.

The plasma channel 22 may be provided with a gas nozzle 22a. The gas nozzle 22a may be used to feed an in-situ clean gas, or a process gas in order to enhance dissociation and ionization rates because electrons in the plasma channel 22 may have a relatively high temperature. The plasma channel 22 may be made from a metal tube or a ceramic tube. If the plasma channel 22 is made from a metal tube, a DC brake 23 may be provided to prevent or reduce induction of plasma current and consequently, to transmit RF power to plasma.

The ferrite core 21 in the form of a closed loop may have a primary-side provided with the antenna coil 25 and a secondary-side under the influence of plasma. The magnetic field 40, which may be created by RF current flowing through the primary-side, may be transmitted to plasma around the secondary-side of the ferrite core 21 having relatively high magnetic permeability, thereby achieving a greater coupling efficiency than a conventional Inductively Coupled Plasma (ICP) manner. Over time, under the influence of the magnetic field 40 created by the primary-side, an inductive electric field 50 may be induced in plasma around the secondary-side. Plasma current having passed through the plasma channel 22 defines a closed loop path, enabling effective generation of plasma. When the plasma channel 22 is made from a metal tube, a DC brake 23 may be inserted to prevent or reduce current from being induced in the metal tube and to effectively transmit RF power to the plasma. Accordingly, the plasma source module 24 may include a ferrite core 21, plasma channel 22, and DC brake 23, and may efficiently transmit plasma, which is generated in the plasma channel 22, into the reactor chamber 10.

FIG. 6 is a plan view illustrating the DC brake. The DC brake may have a body 23a in the form of a divided rectangle. The body 23a may have two holes 23b and 23c that may be symmetrical with each other.

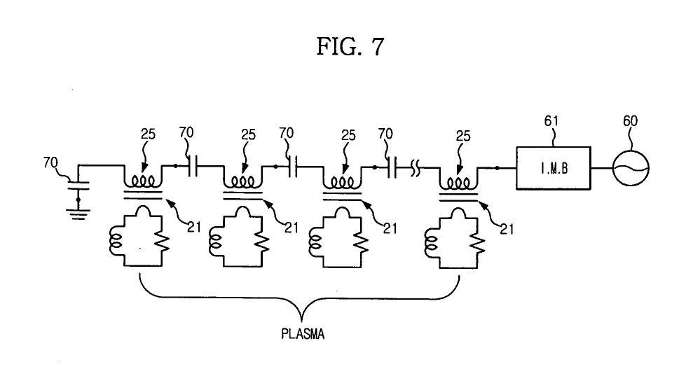

FIG. 7 illustrates an equivalent circuit of the plasma generating apparatus wherein a single RF generator 60 may be connected to the respective antenna coils 25 with an impedance matching box 61 interposed therebetween. As one or more balanced capacitors 70 may be inserted between the plasma source modules 24 wherein the antenna coils 25 are wound on the ferrite cores 21 and a ground terminal end, lowering a voltage to be applied to the respective antenna coils 25 may be possible, and this may prevent or retard the occurrence of arcing between the respective antenna coils 25 and the surrounding structures upon application of RF power.

Hereinafter, an example of an operating sequence and effects of the plasma generating apparatus in accordance with the general inventive concept having the above-described configuration will be described.

In accordance with an example operating sequence, the interior of the reactor chamber 10 may be initially exhausted by a vacuum pump (not shown) to generate a vacuum. A reactant gas to generate plasma may be injected into the reactor chamber 10 through the gas nozzle 11 and the interior of the reactor chamber 10 may be maintained at a desired pressure.

For plasma ignition, the RF generator 30 may apply RF power to the electrode 13 in the reactor chamber 10. Application of the RF power may create the inductive electric field 50 in the reactor chamber 10. The inductive electric field 50 may, in turn, accelerate reactant gas molecules in the reactor chamber 10 to excite and ionize the reactant gas, causing plasma ignition. The initial plasma generation may cause plasma ignition in a CCP manner as the RF generator 30 applies RF power to the electrode 13.

After plasma ignition, RF power may be applied to antenna systems 20a and 20b.

If the RF generators 26a and 26b apply RF power to the antenna coils 25a and 25b of the antenna systems 20a and 20b, current flowing through the antenna coils 25a and 25b may create a sinusoidal magnetic field so as to create an inductive electric field 50 opposite to a current flow direction of the antenna coils 25a and 25b. The inductive electric field 50 may accelerate reactant gas molecules in the reactor chamber 10 to excite and ionize the reactant gas, thereby generating plasma in the reactor chamber 10. Thereby, the workpiece 14 placed on the electrode 13 in the reactor chamber 10 may be subjected to thin-film deposition or etching by plasma.

Accordingly, in the embodiments of the general inventive concept, with the use of the plurality of plasma source modules 24 each having the highly magnetic permeable ferrite core 21, a conventional dielectric window may be eliminated, large-area and high-density plasma may be generated and uniformly distributed, and enhanced plasma generation efficiency may be accomplished by high inductive coupling efficiency between a reactant gas and an inductive electric field.

In the embodiments of the general inventive concept, the primary-side current flowing through the respective antenna coils 25a and 25b may flow in an opposite direction to current induced in the secondary-side plasma, causing an increased magnetic field without loss and resulting in enhanced plasma generation efficiency.

In the embodiments of the general inventive concept, to effectively transmit the magnetic field 40, which may be created by the primary-side current of the antenna coil 25, to the secondary-side plasma, the plasma source module 24 may include the square ring shaped ferrite core 21. Also, the secondary-side plasma may cause a closed loop path of plasma current through the plasma channel 22, improving the density of plasma up to about two times a conventional plasma density. When the plasma channel 22 is made from a metal tube, the DC brake 23 may be provided to prevent or reduce current from being induced to the plasma channel 22, whereby effective transmission of RF power to plasma may be accomplished.

In the embodiments of the general inventive concept, the plasma channel 22 may have an inverted U-shaped form suitable for minimizing or reducing the area of the plasma channel 22. The reduced area may result in a reduction in the loss of plasma.

As apparent from the above description, the general inventive concept may provide a plasma generating apparatus, which may generate and uniformly distribute large-area and high-density plasma, thereby providing high-density plasma for use in a large-area plasma treatment, for example, in the fabrication of TFT LCDs or solar cells.

Although embodiments of the general inventive concept have been shown and described, it would be appreciated by those skilled in the art that changes may be made in this embodiment without departing from the principles and spirit of the general inventive concept, the scope of which is defined in the claims and their equivalents.

What is claimed is:

1. A plasma generating apparatus comprising:
a reactor chamber configured for plasma generation;
an RF generator configured to supply RF power for the plasma generation;
at least one antenna system including a plurality of plasma source modules to create an inductive electric field in the plasma upon receiving the RF power; and
an electrode in the reactor chamber configured to support a workpiece.

2. The apparatus of claim 1, wherein each of the plasma source modules includes a closed-loop shaped ferrite core and a plasma channel defining a space to create a closed loop of plasma current by the inductive electric field in conjunction with the reactor chamber.

3. The apparatus of claim 2, wherein the ferrite core has a square ring form.

4. The apparatus of claim 3, wherein the ferrite core is perpendicular to an upper surface of the reactor chamber.

5. The apparatus of claim 2, wherein the plasma channel has an inverted U-shaped form.

6. The apparatus of claim 2, wherein the plasma channel further includes a gas nozzle.

7. The apparatus of claim 2, wherein the plasma channel is a ceramic tube.

8. The apparatus of claim 1, wherein each of the plasma source modules of the at least one antenna system are arranged on an upper surface of the reactor chamber and are connected with one another in series by an antenna coil connected with the RF generator.

9. The apparatus of claim 7, wherein the at least one antenna system includes a first and second antenna system, the first antenna system including a first group of the plasma source modules arranged in a peripheral region of an upper surface of the reactor chamber, and the second antenna system including a second group of the plasma source modules arranged in a central region of the upper surface of the reactor chamber, and the plasma source modules of each group are connected with one another in series by use of an independent antenna coil.

10. The apparatus of claim 7, wherein the plurality of plasma source modules arranged on an upper surface of the reactor chamber are divided into groups of the same number of plasma source modules and the plasma source modules of each group are connected with one another in series by independent antenna coils.

11. The apparatus of claim 2, wherein the plasma source module further includes a DC brake configured to prevent or reduce current from being induced in the plasma channel and the plasma channel is a metal tube.

12. The apparatus of claim 11, wherein the at least one antenna system includes a first and second antenna system, the first antenna system including a first group of the plasma source modules arranged in a peripheral region of an upper surface of the reactor chamber, and the second antenna system including a second group of the plasma source modules arranged in a central region of the upper surface of the reactor chamber, and the plasma source modules of each group are connected with one another in series by independent antenna coils.

13. The apparatus of claim 11, wherein the plurality of plasma source modules arranged on an upper surface of the reactor chamber are divided into groups of the same number of plasma source modules and the plasma source modules of each group are connected with one another in series by use of an independent antenna coil.

14. A plasma generating apparatus comprising:
a reactor chamber for plasma generation;
an RF generator configured to supply RF power for the plasma generation;
a plurality of plasma source modules each including a closed-loop shaped ferrite core configured to create an inductive electric field in the plasma upon receiving the RF power, and a plasma channel defining a space to create a closed loop of plasma current by the inductive electric field in conjunction with the reactor chamber; and
an antenna coil configured to connect the plurality of plasma source modules in series.

15. The apparatus of claim 14, wherein the ferrite core has a square ring form and is perpendicular to an upper surface of the reactor chamber, and the plasma channel has an inverted U-shaped.

16. The apparatus of claim 15, wherein the plasma channel a ceramic tube.

17. The apparatus of claim 15, wherein the plasma source modules further include a DC brake to prevent current from being induced to the plasma channel and the plasma channel is metal tube.

18. The apparatus of claim 14, wherein the plurality of plasma source modules includes a first group of the plasma source modules arranged in a peripheral region of an upper surface of the reactor chamber, and a second group of the plasma source modules arranged in a central region of the upper surface of the reactor chamber, and the plasma source modules of each group are connected with one another in series by use of independent antenna coils.

19. The apparatus of claim 14, wherein the plurality of plasma source modules are divided into groups of the same number of plasma source modules, and the plasma source modules of each group are connected with one another in series by independent antenna coils.
